(19) United States
(12) Patent Application Publication
(10) Pub. No.: US 2026/0342287 A1
(43) Pub. Date: Oct. 29, 2026

(54) POWER AMPLIFIER INCLUDING BIAS VOLTAGE BASED GAIN TEMPERATURE COMPENSATION

(71) Applicant: QUALCOMM Incorporated, San Diego, CA (US)

(72) Inventors: Zhenying LUO, Wayland, MA (US); Xinwei WANG, Dunstable, MA (US); Yazhou WANG, Westford, MA (US); Jisun RYU, Sudbury, MA (US); Xiangdong ZHANG, Westford, MA (US)

(21) Appl. No.: 19/190,067

(22) Filed: Apr. 25, 2025

(51) Int. Cl. H03F 1/30; H03F 3/24; H04B 1/38

(52) U.S. Cl. CPC H03F 1/302; H03F 3/245; H04B 1/38; H03F 2200/451

(57) ABSTRACT

A power amplifier (PA) circuit, comprising: a power amplifier (PA); a current source configured to generate a reference current that flows into a first node situated between the current source and a current summing node, wherein a reference voltage is generated at the current summing node; and a temperature compensation circuit configured to provide or draw a temperature compensating current to or from the current summing node in response to the reference voltage varying with an operating temperature of the PA, wherein a bias current is generated at the current summing node that flows to the PA.

### FIELD

This disclosure relates generally to power amplifiers (PAs), and in particular, to a power amplifier (PA) including bias voltage-based gain temperature compensation.

### BACKGROUND

[0002]A transmitter or transceiver often includes a power amplifier (PA) to amplify a radio frequency (RF) signal prior to be sent to an antenna for wireless transmission. Typically, the PA consumes significant power to effectuate the amplification so that the transmitted RF signal has sufficient power for needed long distance wireless transmission. As a result of the PA’s high power consumption, the operating temperature of the PA increases. The increase in operating temperature may affect or lower the gain of the PA, which may be undesirable.

### SUMMARY

[0003]The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a power amplifier (PA) circuit. The PA circuit, comprises: a power amplifier (PA); a current source configured to generate a reference current that flows into a current summing node situated between the current source and the PA, wherein a reference voltage is generated at the current summing node; and a temperature compensation circuit configured to supply or draw a temperature compensating current to or from the current summing node in response to the reference voltage varying with an operating temperature of the PA, wherein a bias current is generated at the current summing node that flows to the PA.

An aspect of the disclosure relates to a transceiver. The transceiver includes: a modem configured to generate a transmit baseband signal; a frequency upconverting circuit configured to frequency upconvert the transmit baseband signal to generate a first radio frequency (RF) signal; and a power amplifier (PA) circuit, comprising: a power amplifier (PA) configured to amplify the first RF signal to generate a second RF signal; a current source configured to generate a reference current that flows into a current summing node situated between the current source and the PA, wherein a reference voltage is generated at the current summing node; and a temperature compensation circuit configured to supply or draw a temperature compensating current to or from the current summing node in response to the reference voltage varying with an operating temperature of the PA, wherein a bias current is generated at the current summing node that flows into the PA.

Another aspect of the disclosure relates to a method of temperature compensating a gain of a power amplifier (PA). The method includes: generating a reference current flowing to a current summing node; generating a reference voltage at the current summing node, the reference voltage varying with an operating temperature of the PA; generating a temperature compensating current based on the reference voltage; supplying or drawing the temperature compensating current to or from the current summing node to generate a bias current; and providing the bias current to the PA.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a schematic diagram of an example power amplifier (PA) in accordance with an aspect of the disclosure.

FIG. 1B illustrates a graph of an example output power versus time associated with the power amplifier (PA) of FIG. 1A in accordance with another aspect of the disclosure.

FIG. 2A illustrates a block diagram of an example power amplifier (PA) circuit 200 with a temperature compensation circuit in accordance with another aspect of the disclosure.

FIG. 2B illustrates a graph of an example output power versus time associated with the power amplifier (PA) with the temperature compensation circuit of FIG. 2A in accordance with another aspect of the disclosure.

FIG. 3 illustrates a schematic diagram of an example power amplifier (PA) circuit with a temperature compensation circuit in accordance with another aspect of the disclosure.

FIG. 4 illustrates a schematic diagram of another example power amplifier (PA) circuit with a temperature compensation circuit in accordance with another aspect of the disclosure.

FIG. 5 illustrates a schematic diagram of another example power amplifier (PA) circuit with a temperature compensation circuit in accordance with another aspect of the disclosure.

FIG. 6 illustrates a block diagram of an example transceiver in accordance with another aspect of the disclosure.

FIG. 7 illustrates a block diagram of an example wireless communication system in accordance with another aspect of the disclosure.

FIG. 8 illustrates an example method of temperature compensating a gain of a power amplifier (PA) in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

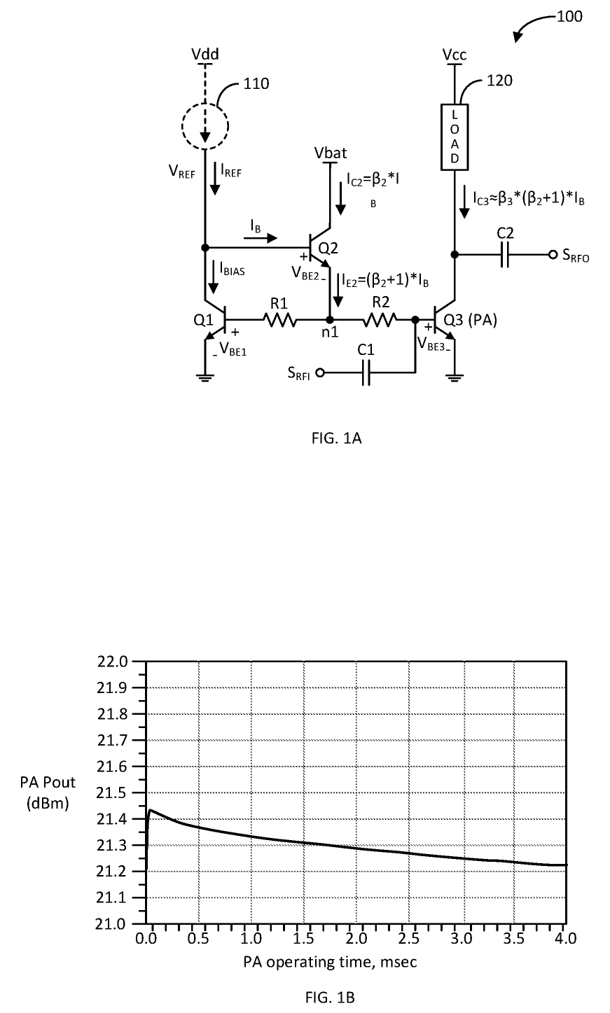

FIG. 1A illustrates a schematic diagram of an example power amplifier (PA) 100 in accordance with an aspect of the disclosure. The PA 100 includes a reference current source 110, a first bipolar junction transistor (BJT) Q1, a second BJT Q2, a third BJT Q3, bias resistors R1 and R2, alternating current (AC) coupling capacitors C1 and C2, and an output load 120. As indicated by dashed lines, the reference current source 110 may be implemented in an integrated circuit (IC) (e.g., a silicon (Si) IC) separate from an IC (e.g., gallium-arsenide (GaAs)) in which the PA 100 may be implemented.

The reference current source 110 is configured to generate a substantially constant reference current IREF. The reference current source 110 is coupled in series with the first BJT Q1 between a first upper voltage rail Vdd and a lower voltage rail (e.g., ground). That is, the reference current source 110 is coupled between the first upper voltage rail Vdd and a collector of the first BJT Q1. The first BJT Q1 includes an emitter coupled to the lower voltage rail. In this example, the constant reference current IREF provides a bias (collector) current IBIAS through the first BJT Q1 and a small base current IB for the second BJT Q2 (e.g., IREF=IBIAS+IB). A bias reference voltage VREF is generated at the collector of the first BJT Q1 and the base of the second BJT Q2.

The second BJT Q2 is coupled between a second upper voltage rail Vbat (e.g., a positive battery terminal) and an internal node n1. That is, the second BJT Q1 includes a collector coupled to the second upper voltage rail Vbat, and an emitter coupled to the internal node n1. The first resistor R1 is coupled between the internal node n1 and a base of the first BJT Q1. The second resistor R2 is coupled between the internal node n1 and a base of the third BJT Q3. The second BJT Q2, serving as a beta helper, is configured to amplify the base current IB by a current gain β2 to generate a collector current IC2=β2*IB and an emitter current IE2=(β2+1)*IB. The size of the first BJT Q1 may be significantly smaller than the size of the third BJT Q3 (e.g., Q1/Q3=1/50 to 1/100, where Q1 and Q3 also represent the sizes of the BJTs Q1 and Q3, respectively). So that the base-to-emitter voltage VBE1 of the first BJT Q1 is substantially equal to the base-to-emitter voltage VBE3 of the third BJT Q3 (e.g., to effectuate accurate mirroring of the bias current IBIAS to the collector current IC3 of the third BJT Q3 by a current gain of Q3/Q1), the ratio of the resistances of resistors R1 and R2 (e.g., R1/R2) should be substantially equal to the size ratio Q3/Q1 of the third and first BJTs Q3 and Q1, respectively (e.g., R1/R2=Q3/Q2). Accordingly, the base current to the third BJT Q3 is substantially or approximately equal to the emitter current IE2=(β2+1)*IB of the second BJT Q2.

The output load 120 is coupled in series with the third BJT between a third upper voltage rail Vcc and the lower voltage rail (e.g., ground). That is, the output load 120 is coupled between the third upper voltage rail Vcc and the collector of the third BJT Q3. The third BJT Q3 includes an emitter coupled to the lower voltage rail (e.g., ground). The third BJT Q3 is configured to amplify its substantial or approximated base current (β2+1)*IB with a current gain of β3 to generate a collector current IC3≈β3*(β2+1)*IB. As discussed, due to the current mirror configuration of BJTs Q1 and Q3, the collector current IC3 of the third BJT Q3 is directly related (e.g., by current gain Q3/Q1) to the bias current IBIAS of the first BJT Q1.

The input AC coupling capacitor C1 includes a first terminal configured to receive an input radio frequency (RF) signal SRFI and a second terminal coupled to the base of the third BJT Q3. The output AC coupling capacitor C2 includes a first terminal coupled to the collector of the third BJT Q3 (or more generally, a node between the output load 120 and the collector of the third BJT Q3). The output AC coupling capacitor C2 is configured to produce an output RF signal SRFO. Accordingly, the third BJT Q3 is the RF signal amplification component of the PA 100.

When the PA 100 is being operated, the third BJT Q3 generates significant heat. As the first and second BJTs Q1 and Q2 may be thermally coupled to the third BJT Q3, the first and second BJTs Q1 and Q2 also heat up with the operation of the PA 100. The base-to-emitter voltages VBE1 and VBE2 of the first and second BJTs Q1 and Q2 are sensitive to heat; and typically, decrease by, for example, two (2) milliVolts (mV) for each degree Celsius (°C) increase in the PA operating temperature. As exemplified further herein, the decrease in the base-to-emitter voltages VBE1 and VBE2 with PA operating temperature, reduces the gain of the PA 100.

FIG. 1B illustrates a graph of an example output power (Pout) versus time associated with the PA 100 in accordance with another aspect of the disclosure. The vertical axis of the graph represents the output power Pout of the output RF signal SRFO of the PA 100 in decibel-milliwatt (dBm) ranging from 21.0 dBm to 22.0 dBm. The horizontal axis represents the PA operating time in milliseconds (msec) ranging from 0.0 msec to 4.0 msec. As the graph illustrates, the output power Pout or gain of the PA 100 decreases from about 21.43 dBm at time 0.0 msec when the PA 100 is enabled to 21.22 dBm after being operated for 4 msec. The decrease in the Pout or gain is attributed to the PA 100 (e.g., specifically BJTs Q1, Q2, and Q3) heating up while being operated. It may be preferred for the PA 100 to maintain a substantially constant Pout or gain with increasing PA operating temperature.

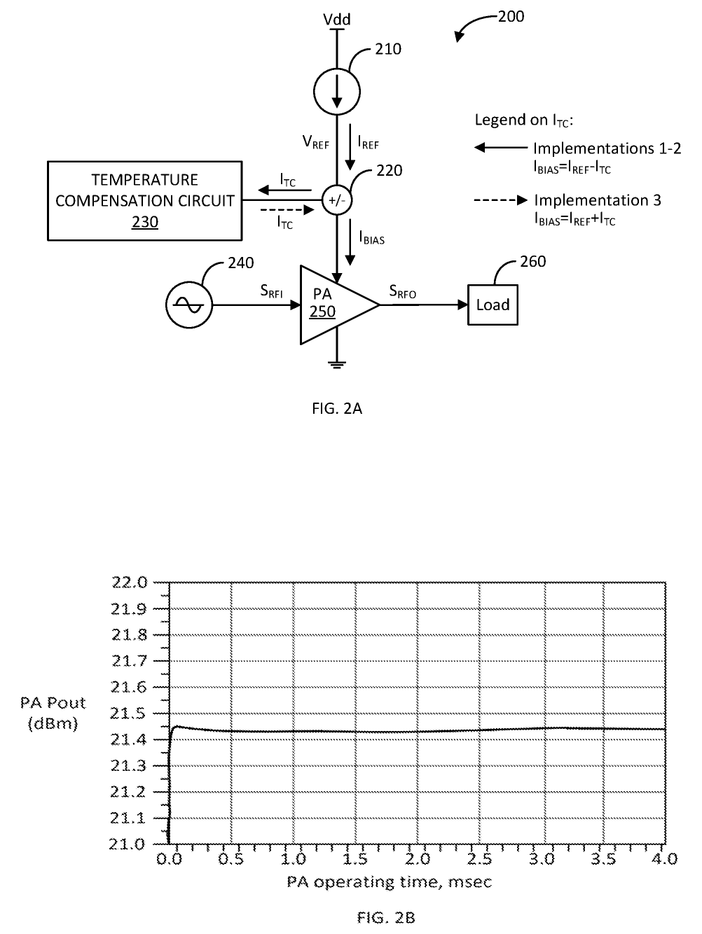

FIG. 2A illustrates a block diagram of an example power amplifier (PA) circuit 200 with a temperature compensation circuit 230 in accordance with another aspect of the disclosure. As discussed further herein, the temperature-compensated PA circuit 200 increases the bias current IBIAS provided to a PA 250 with increasing PA operating temperature. As previously discussed, the collector (bias) current IC3 for the RF amplification third BJT Q3 is related to the bias current IBIAS. Accordingly, by increasing the bias current IBIAS with the PA operating temperature, the gain of the PA 250 tends to increase, which counters the decrease in gain of the PA 250 due to the decrease in the base-to-emitter voltages VBE1 and VBE2 of the first and second BJTs Q1 and Q2, respectively.

In particular, the PA circuit 200 includes a reference current source 210, a current summing node 220, a temperature compensation circuit 230, a radio frequency (RF) signal source 240, the PA 250, and a load 260 (e.g., an antenna and/or other related circuitry, such as a coupler). The reference current source 210 is coupled between an upper voltage rail Vdd and an input to the current summing node 220. The current summing node 220 includes an input or output coupled to the temperature compensation circuit 230. The PA 250 is coupled between an output of the current summing node 220 and a lower voltage rail (e.g., ground). The PA 250 includes an input coupled to the RF signal source 240 to receive an input RF signal SRFI. The PA 250 is configured to amplify the input RF signal SRFI with a gain to generate an output RF signal SRFO, which is provided to the load 260.

As discussed, if not compensated, the gain of the PA 250 (or output power Pout of the output RF signal SRFO) decreases with increasing PA operating temperature. The current summing node 220 coupled to the temperature compensation circuit 230 is configured to increase the bias current IBIAS provided to the PA 250 to compensate for the gain decrease due to increasing PA operating temperature.

In implementations 1-2 (see Legend on ITC) as discussed further herein, the temperature compensation circuit 230 reduces a temperature compensating current ITC (shown as a solid arrow line) (e.g., in response to a decrease in the bias reference voltage VREF) it draws from the current summing node 220 with increasing PA operating temperature. This causes the bias current IBIAS provided to the PA 250 to increase (e.g., in accordance with the equation IBIAS=IREF-ITC) to compensate for the gain decrease due to increasing PA operating temperature. In implementation 3 (see Legend on ITC) as discussed further herein, the temperature compensation circuit 230 increases a temperature compensating current ITC (shown as a dashed arrow line) (e.g., in response to a decrease in the bias reference voltage VREF) supplied to the current summing node 220 with increasing PA operating temperature. This causes the bias current IBIAS provided to the PA 250 to increase (e.g., in accordance with the equation IBIAS=IREF+ITC) to compensate for the gain decrease due to increasing PA operating temperature.

]FIG. 2B illustrates a graph of an example output power (Pout) versus time associated with the power amplifier (PA) circuit 200 in accordance with another aspect of the disclosure. The graph is similar to the graph of FIG. 1B. As shown, the temperature-compensation provided by the temperature compensation circuit 230 causes the gain of the PA 250 to be substantially constant over the PA operating time (e.g., at substantially 21.43 dBm from 0.0 msec to 4.0 msec).

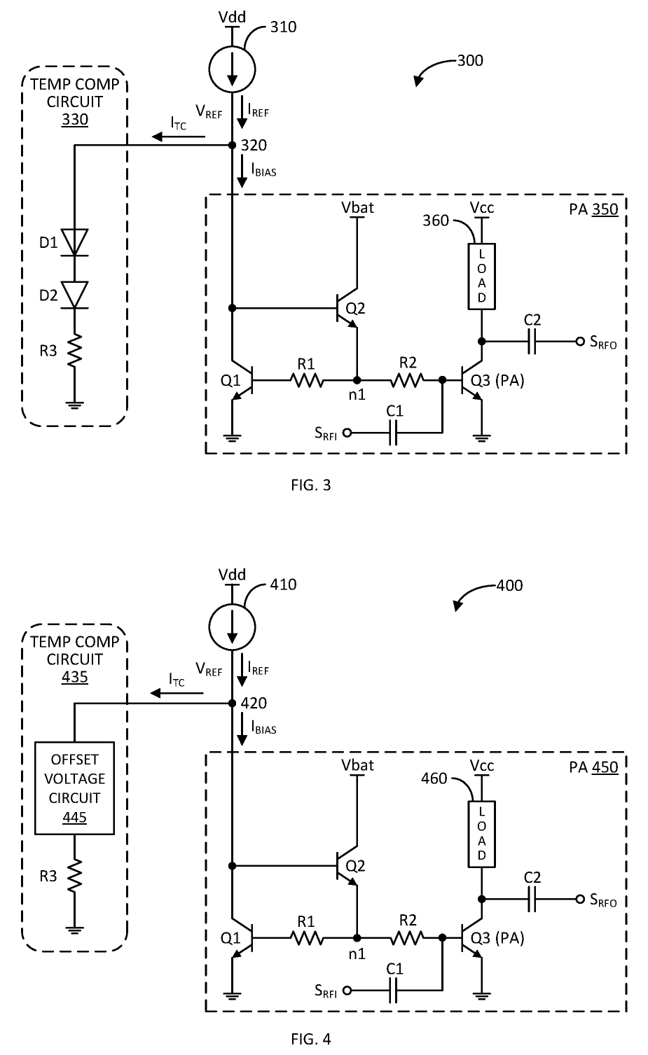

FIG. 3 illustrates a schematic diagram of another example power amplifier (PA) circuit 300 in accordance with another aspect of the disclosure. The PA circuit 300 may be an example implementation of the PA circuit 200 previously discussed.

In particular, the PA circuit 300 includes a reference current source 310, a current summing node 320, a temperature compensation circuit 330, and a PA 350. The PA 350, in turn, includes BJTs Q1-Q3, resistors R1-R2, AC coupling capacitors C1-C2, and an output load 360 in a similar configuration as PA 100. The temperature compensation circuit 330 includes a pair of forward-biased diodes D1-D2 coupled in series with a resistor R3 between the current summing node 320 and a lower voltage rail (e.g., ground).

In operation, the base-to-emitter voltages VBE1 and VBE2 of the BJTs Q1 and Q2 decrease with increasing PA operating temperature. As a bias reference voltage VREF generated at the current summing node 320 is related to VBE1 and VBE2, the reference voltage VREF also decreases with increasing operating temperature of the PA 350 (e.g., by -4mV/°C). The decrease in the reference voltage VREF causes the temperature compensating current ITC drawn by the temperature compensation circuit 330 to decrease. As the reference current IREF is substantially constant, the bias current IBIAS increases with the decrease in the temperature compensating current ITC in accordance with the following equation: IBIAS=IREF-ITC. The increase in the bias current IBIAS compensates for the PA’s gain decrease due to increasing PA operating temperature.

The pair of forward-biased diodes D1-D2 operate to generate a voltage offset (similar to the base-emitter pn junctions of the BJTs Q1-Q2) to maintain the reference voltage VREF at a certain level needed for the PA 350 (e.g., Q1, Q2, and Q3) to operate.

FIG. 4 illustrates a schematic diagram of another example power amplifier (PA) circuit 400 in accordance with another aspect of the disclosure. The PA circuit 400 may be an example implementation of the PA circuit 200 previously discussed. The PA circuit 400 is similar to PA circuit 300 including many of the same/similar elements as indicated by the same reference identifiers and numbers but with the exception that their most significant digit is a “4” in PA circuit 400 instead of a “3” in PA circuit 300.

The PA 400 differs from PA 300 in that PA 400 includes a temperature compensation circuit 435 including an offset voltage circuit 445 coupled in series with a resistor R3 between the current summing node 420 and the lower voltage rail (e.g., ground). The offset voltage circuit 445 is configured to generate an offset voltage of substantially 2*VBE (e.g., where VBE=VBE1=VBE2) so that the bias reference voltage VREF is maintained at a certain level for proper operation of the PA 450.

In one implementation, the offset voltage circuit 445 may be a bandgap voltage generator configured to generate a substantially constant-temperature offset voltage drop between the current summing node 420 and the resistor R3. In response to the reference voltage VREF decreasing with the operating temperature of the PA 450, the temperature compensating current ITC drawn by the temperature compensation circuit 435 from the current summing node 420 decreases. As the reference current IREF is substantially constant, the bias current IBIAS increases with the decrease in the temperature compensating current ITC in accordance with the following equation: IBIAS=IREF-ITC. The increase in the bias current IBIAS compensates for the PA’s gain decrease due to increasing PA operating temperature.

In another implementation, the offset voltage circuit 445 may be implemented as a proportional to absolute temperature (PTAT) voltage generator configured to generate a PTAT offset voltage drop between the current summing node 420 and the resistor R3. In response to the bias reference voltage VREF decreasing with temperature, the temperature compensating current ITC drawn by the temperature compensation circuit 435 from the current summing node 420 decreases. As the reference current IREF is substantially constant, the bias current IBIAS increases with the decrease in the temperature compensating current ITC in accordance with the following equation: IBIAS=IREF-ITC. The increase in the bias current IBIAS compensates for the PA’s gain decrease due to increasing PA temperature.

In the case of the PTAT offset voltage generator 445, the temperature compensation circuit 435 reduces the temperature compensating current ITC by a greater amount compared to if the offset voltage circuit 445 is implemented as a bandgap offset voltage generator. This may cause the bias current IBIAS to increase by a greater amount to, perhaps, provide a gain augmentation of the PA 450 with increasing PA operating temperature.

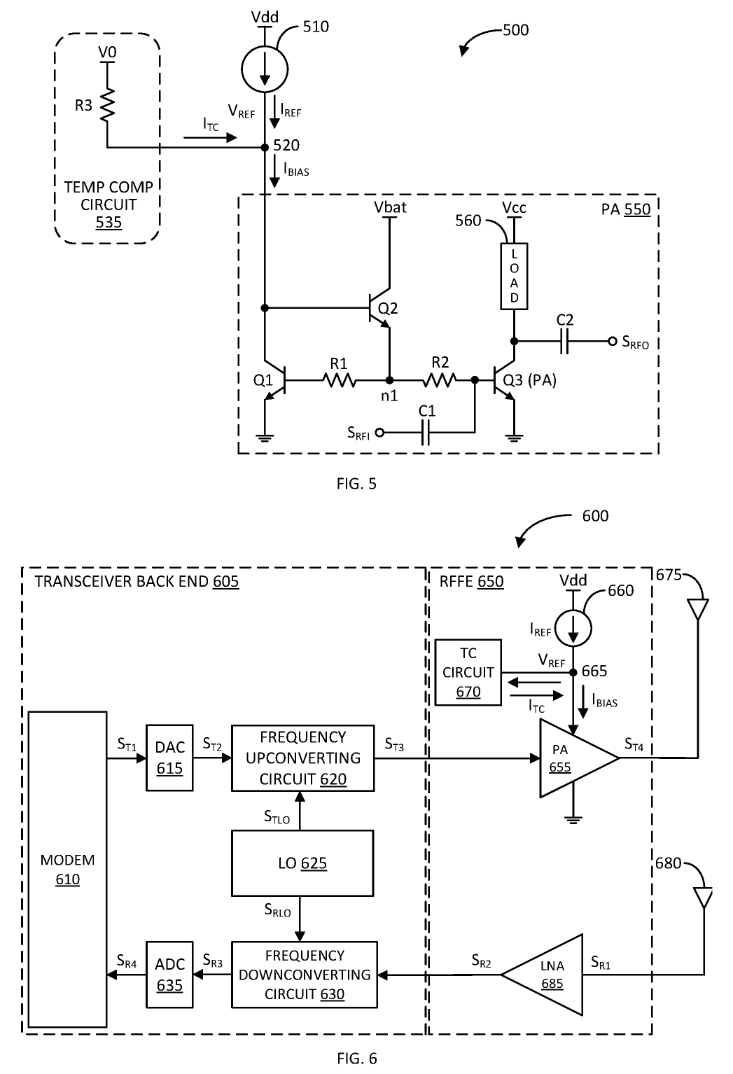

FIG. 5 illustrates a schematic diagram of another example power amplifier (PA) circuit 500 in accordance with another aspect of the disclosure. The PA circuit 500 may be an example implementation of the PA circuit 200 previously discussed. The PA circuit 500 is similar to PA circuit 300 including many of the same/similar elements as indicated by the same reference identifiers and numbers but with the exception that their most significant digit is a “5” in PA circuit 500 instead of a “3” in PA circuit 300.

The PA circuit 500 differs from PA circuit 300 in that PA circuit 500 includes a temperature compensation circuit 535 including a resistor R3 coupled between an upper voltage rail V0 and the current summing node 520. In response to the bias reference voltage VREF decreasing with the operating temperature of the PA 550, the temperature compensation circuit 535 increases a temperature compensating current ITC supplied to the current summing node 520. This causes the bias current IBIAS to increase in accordance with the following equation: IBIAS=IREF+ITC. The increase in the bias current IBIAS compensates for the PA’s gain decrease due to increasing PA operating temperature.

FIG. 6 illustrates a block diagram of an example transceiver 600 in accordance with another aspect of the disclosure. As discussed further herein, the transceiver 600 may include any one of the power amplifier (PA) circuits 200, 300, 400, and 500 described herein. The transceiver 600 includes a transceiver back end 605, a radio frequency front end (RFFE) 650, a transmit antenna 675, and a receive antenna 680. Although, in this example, the transceiver 600 includes separate transmit and receive antennas 675 and 680, it shall be understood that the transceiver 600 may include an antenna common to both transmission and reception.

The transceiver back end 605 includes a modem 610, a digital-to-analog converter (DAC) 615, a frequency upconverting circuit 620, a local oscillator (LO) 625, a frequency downconverting circuit 630, and an analog-to-digital converter (ADC) 635. The RFFE 650 includes a power amplifier (PA) 655, a constant reference current source 660, a current summing node 665, a temperature compensation (TC) circuit 670, and a low noise amplifier (LNA) 685.

With regard to transmission, the modem 610 is configured to generate a digital transmit baseband signal ST1. The DAC 615 is configured to convert the digital transmit baseband signal ST1 into an analog transmit baseband signal ST2. The frequency upconverting circuit 620 is configured to frequency upconvert the analog transmit baseband signal ST2 using one or more transmit local oscillator signal STLO to generate a first transmit radio frequency (RF) signal ST3. It shall be understood that the frequency upconverting circuit 620 may perform the frequency up conversion in more than one stage; for example, by frequency upconverting the analog transmit baseband signal ST2 into an intermediate frequency (IF) signal, and then, frequency upconverting the IF signal to generate the first transmit RF signal ST3.

Continuing with the transmission, the PA 655 is configured to amplify the first transmit RF signal ST3 to generate a second transmit RF signal ST4. As discussed with reference to PA circuits 200, 300, 400, and 500, the constant reference current source 660, the current summing node 665, and the temperature compensation circuit 670 are collectively configured to provide a bias current IBIAS for the PA 655 that increases with the PA’s operating temperature as indicated by a decreasing bias reference voltage VREF at the current summing node 665. The second transmit RF signal ST4 is provided to the transmit antenna 675 for wireless transmission.

With regard to reception, the receive antenna 680 is configured to wirelessly pickup/sense a first received RF signal SR1. The LNA 685 is configured to amplify the first received RF signal SR1 to generate a second received RF signal SR2.

Continuing with the reception, the frequency downconverting circuit 630 is configured to frequency downconvert the second received RF signal SR2 using one or more receive local oscillator signal SRLO to generate an analog received baseband signal SR3. It shall be understood that the frequency downconverting circuit 630 may perform the frequency down conversion in more than one stage; for example, by frequency downconverting the second received RF signal SR2 into an intermediate frequency (IF) signal, and then, frequency downconverting the IF signal to generate the analog received baseband signal SR3. The ADC 635 is configured to convert the analog received baseband signal SR3 into a digital received baseband signal SR4. The modem 610 is configured to receive and process the digital received baseband signal SR4 to extract/recover data/information therein.

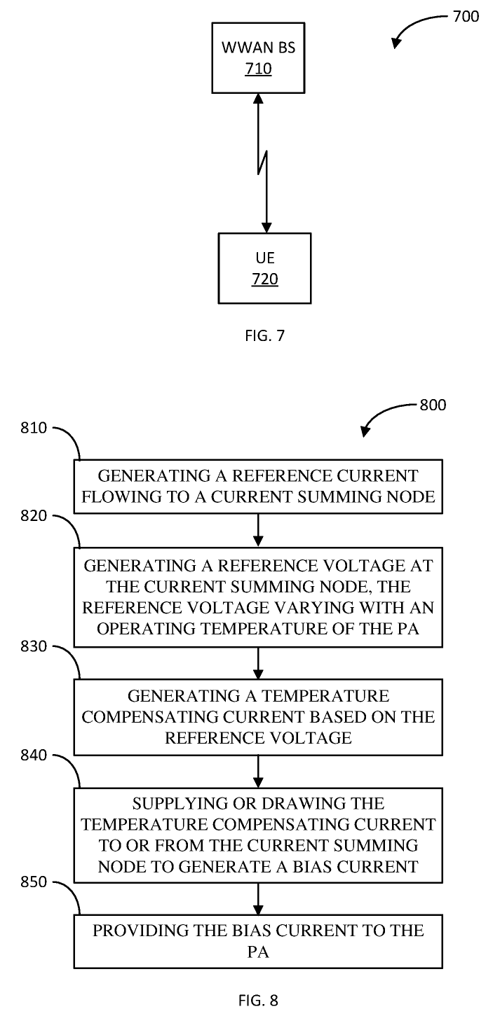

FIG. 7 illustrates a block diagram of an example wireless communication system 700 in accordance with another aspect of the disclosure. The wireless communication system 700 includes a wireless wideband area network (WWAN) base station (BS) 710 and a user equipment (UE) 720. The WWAN BS 710 and UE 720 may wirelessly communicate with each other in accordance with various protocols, such as New Radio (NR) 5th or 6th Generation (5G) or (6G), or other. Further, although a WWAN is used to exemplify the concepts described herein, it shall be understood that the concepts described herein may be applicable to wireless local area networks (WLANs) (e.g., WiFi), short distance area networks (e.g., Bluetooth), personal area networks, ultra-wideband (UWB) based wireless networks, etc. The UE 720 and/or the WWAN BS 710 may include any one of the temperature-compensated PA circuits described herein.

FIG. 8 illustrates an example method 800 of temperature compensating a gain of a power amplifier (PA) in accordance with another aspect of the disclosure. The method 800 includes generating a reference current flowing to a current summing node (block 810). Examples of means for generating a reference current flowing to a current summing node include any one of reference current sources 210, 310, 410, 510, and 660. The method 800 further includes generating a reference voltage at the current summing node, the reference voltage varying with an operating temperature of the PA (block 820). Examples of means for generating a reference voltage at the current summing node, the reference voltage varying with an operating temperature of the PA include any one of reference current sources 210, 310, 410, 510, and 660.

The method 800 also includes generating a temperature compensating current based on the reference voltage (block 830). Examples of means for generating a temperature compensating current based on the reference voltage include any one of the temperature compensation circuits 230, 330, 435, 535, and 670. Additionally, the method 800 includes supplying or drawing the temperature compensating current to or from the current summing node to generate a bias current (block 840). Examples of means for supplying or drawing the temperature compensating current to or from the current summing node to generate a bias current include any one of the current summing nodes 220, 320, 420, 520, and 665. Further, the method 800 includes providing the bias current to the PA (block 850). Examples of means for providing the bias current to the PA includes any of the coupling of the current summing nodes 220, 320, 420, 520, and 665 to the PAs 250, 350, 450, 550, and 655, respectively.

The following provides an overview of aspects of the present disclosure:
Aspect 1: A power amplifier (PA) circuit, comprising: a power amplifier (PA); a current source configured to generate a reference current that flows into a current summing node situated between the current source and the PA, wherein a reference voltage is generated at the current summing node; and a temperature compensation circuit configured to supply or draw a temperature compensating current to or from the current summing node in response to the reference voltage varying with an operating temperature of the PA, wherein a bias current is generated at the current summing node that flows to the PA.
Aspect 2: The PA circuit of aspect 1, wherein the temperature compensation circuit is configured to supply or draw the temperature compensating current to increase the bias current that flows into the PA with increasing operating temperature of the PA.
Aspect 3: The PA circuit of aspect 1 or 2, wherein the temperature compensation circuit is configured to supply or draw the temperature compensating current so that the bias current controls a gain of the PA with variation in the operating temperature of the PA.
Aspect 4: The PA circuit of any one of aspects 1-3, wherein the temperature compensation circuit is configured to supply or draw the temperature compensating current so that the bias current maintains a gain of the PA substantially constant with variation in the operating temperature of the PA. Aspect 5: The PA circuit of any one of aspects 1-4, wherein the temperature compensation circuit comprises one or more diodes coupled in series with a resistor between the current summing node and a lower voltage rail.
Aspect 6: The PA circuit of any one of aspects 1-4, wherein the temperature compensation circuit comprises an offset voltage circuit coupled in series with a resistor between the current summing node and a lower voltage rail.
Aspect 7: The PA circuit of aspect 6, wherein the offset voltage circuit comprises a bandgap voltage generator.
Aspect 8: The PA circuit of aspect 6, wherein the offset voltage circuit comprises a proportional to absolute temperature (PTAT) voltage generator. Aspect 9: The PA circuit of any one of aspects 1-4, wherein the temperature compensation circuit comprises a resistor coupled between an upper voltage rail and the current summing node.
Aspect 10: The PA circuit of any one of aspects 1-9, wherein the PA comprises: a first bipolar transistor (BJT) including a first collector and a first emitter coupled in series between the current summing node and a lower voltage rail, wherein the first BJT further includes a first base; a second BJT including a second base coupled to the current summing node, and a second collector and a second emitter coupled between a first upper voltage rail and a node; a load; a third BJT including a third collector and a third emitter coupled in series with the load between a second upper voltage rail and the lower voltage rail, and a third base; a first resistor coupled between the node and the first base of the first BJT; and a second resistor coupled between the node and the third base of the third BJT, wherein the third base is configured to receive an input radio frequency (RF) signal, and the third collector is configured to generate an output RF signal.
Aspect 11: A transceiver, comprising: a modem configured to generate a transmit baseband signal; a frequency upconverting circuit configured to frequency upconvert the transmit baseband signal to generate a first radio frequency (RF) signal; and a power amplifier (PA) circuit, comprising: a power amplifier (PA) configured to amplify the first RF signal to generate a second RF signal; a current source configured to generate a reference current that flows into a current summing node situated between the current source and the PA, wherein a reference voltage is generated at the current summing node; and a temperature compensation circuit configured to supply or draw a temperature compensating current to or from the current summing node in response to the reference voltage varying with an operating temperature of the PA, wherein a bias current is generated at the current summing node that flows into the PA.
Aspect 12: The transceiver of aspect 11, wherein the temperature compensation circuit comprises one or more diodes coupled in series with a resistor between the current summing node and a lower voltage rail.
Aspect 13: The transceiver of aspect 11, wherein the temperature compensation circuit comprises an offset voltage circuit coupled in series with a resistor between the current summing node and a lower voltage rail.
Aspect 14: The transceiver of aspect 11, wherein the temperature compensation circuit comprises a resistor coupled between an upper voltage rail and the current summing node.
Aspect 15: The transceiver of any one of aspects 11-14, further comprising: a low noise amplifier (LNA) configured to amplify a first received RF signal to generate a second received RF signal; and a frequency downconverting circuit configured to frequency downconvert the second received RF signal to generate a received baseband signal, wherein the modem is configured to process the received baseband signal to generate data or information.
Aspect 16: A method of temperature compensating a gain of a power amplifier (PA), comprising: generating a reference current flowing to a current summing node; generating a reference voltage at the current summing node, the reference voltage varying with an operating temperature of the PA; generating a temperature compensating current based on the reference voltage; supplying or drawing the temperature compensating current to or from the current summing node to generate a bias current; and providing the bias current to the PA.
Aspect 17: The method of aspect 16, wherein supplying the temperature compensating current to the current summing node comprises coupling an upper voltage rail to the current summing node via a resistor.
Aspect 18: The method of aspect 16, wherein drawing the temperature compensating current from the current summing node comprises coupling the current summing node to a lower voltage rail via one or more diodes and a resistor.
Aspect 19: The method of aspect 16, wherein drawing the temperature compensating current from the current summing node comprises coupling the current summing node to a lower voltage rail via an offset voltage generator and a resistor.
Aspect 20: The method of any one of aspects 16-19, further comprising controlling the gain of the PA based on the bias current.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples described herein but is to be accorded the widest scope consistent with the principles and novel features disclosed herein.

What is claimed:

1. A power amplifier (PA) circuit, comprising:
a power amplifier (PA);
a current source configured to generate a reference current that flows into a current summing node situated between the current source and the PA, wherein a reference voltage is generated at the current summing node; and
a temperature compensation circuit configured to supply or draw a temperature compensating current to or from the current summing node in response to the reference voltage varying with an operating temperature of the PA, wherein a bias current is generated at the current summing node that flows into the PA.

2. The PA circuit of claim 1, wherein the temperature compensation circuit is configured to supply or draw the temperature compensating current to increase the bias current that flows into the PA with increasing operating temperature of the PA.

3. The PA circuit of claim 1, wherein the temperature compensation circuit is configured to supply or draw the temperature compensating current so that the bias current controls a gain of the PA with variation in the operating temperature of the PA.

4. The PA circuit of claim 1, wherein the temperature compensation circuit is configured to supply or draw the temperature compensating current so that the bias current maintains a gain of the PA substantially constant with variation in the operating temperature of the PA.

5. The PA circuit of claim 1, wherein the temperature compensation circuit comprises one or more diodes coupled in series with a resistor between the current summing node and a lower voltage rail.

6. The PA circuit of claim 1, wherein the temperature compensation circuit comprises an offset voltage circuit coupled in series with a resistor between the current summing node and a lower voltage rail.

7. The PA circuit of claim 6, wherein the offset voltage circuit comprises a bandgap voltage generator.

8. The PA circuit of claim 6, wherein the offset voltage circuit comprises a proportional to absolute temperature (PTAT) voltage generator.

9. The PA circuit of claim 1, wherein the temperature compensation circuit comprises a resistor coupled between an upper voltage rail and the current summing node.

10. The PA circuit of claim 1, wherein the PA comprises:
a first bipolar transistor (BJT) including a first collector and a first emitter coupled in series between the current summing node and a lower voltage rail, wherein the first BJT further includes a first base;
a second BJT including a second base coupled to the current summing node, and a second collector and a second emitter coupled between a first upper voltage rail and a node;
a load;
a third BJT including a third collector and a third emitter coupled in series with the load between a second upper voltage rail and the lower voltage rail, and a third base;
a first resistor coupled between the node and the first base of the first BJT; and
a second resistor coupled between the node and the third base of the third BJT, wherein the third base is configured to receive an input radio frequency (RF) signal, and the third collector is configured to generate an output RF signal.

11. A transceiver, comprising:
a modem configured to generate a transmit baseband signal;
a frequency upconverting circuit configured to frequency upconvert the transmit baseband signal to generate a first radio frequency (RF) signal; and
a power amplifier (PA) circuit, comprising:
a power amplifier (PA) configured to amplify the first RF signal to generate a second RF signal;
a current source configured to generate a reference current that flows into a current summing node situated between the current source and the PA, wherein a reference voltage is generated at the current summing node; and
a temperature compensation circuit configured to supply or draw a temperature compensating current to or from the current summing node in response to the reference voltage varying with an operating temperature of the PA, wherein a bias current is generated at the current summing node that flows into the PA.

12. The transceiver of claim 11, wherein the temperature compensation circuit comprises one or more diodes coupled in series with a resistor between the current summing node and a lower voltage rail.

13. The transceiver of claim 11, wherein the temperature compensation circuit comprises an offset voltage circuit coupled in series with a resistor between the current summing node and a lower voltage rail.

14. The transceiver of claim 11, wherein the temperature compensation circuit comprises a resistor coupled between an upper voltage rail and the current summing node.

15. The transceiver of claim 11, further comprising:
a low noise amplifier (LNA) configured to amplify a first received RF signal to generate a second received RF signal; and
a frequency downconverting circuit configured to frequency downconvert the second received RF signal to generate a received baseband signal, wherein the modem is configured to process the received baseband signal to generate data or information.

16. A method of temperature compensating a gain of a power amplifier (PA), comprising:
generating a reference current flowing to a current summing node;
generating a reference voltage at the current summing node, the reference voltage varying with an operating temperature of the PA;
generating a temperature compensating current based on the reference voltage;
supplying or drawing the temperature compensating current to or from the current summing node to generate a bias current; and
providing the bias current to the PA.

17. The method of claim 16, wherein supplying the temperature compensating current to the current summing node comprises coupling an upper voltage rail to the current summing node via a resistor.

18. The method of claim 16, wherein drawing the temperature compensating current from the current summing node comprises coupling the current summing node to a lower voltage rail via one or more diodes and a resistor.

19. The method of claim 16, wherein drawing the temperature compensating current from the current summing node comprises coupling the current summing node to a lower voltage rail via an offset voltage generator and a resistor.

20. The method of claim 16, further comprising controlling the gain of the PA based on the bias current.
